(19) United States
(12) Patent Application Publication
(10) Pub. No.: US 2001/0028099 A1
(43) Pub. Date: Oct. 11, 2001

(54) Semiconductor device and manufacturing method therefor

(75) Inventor: Nolifumi Sato, Tokyo (JP)

Correspondence Address: YOUNG & THOMPSON, 745 SOUTH 23RD STREET 2ND FLOOR, ARLINGTON, VA, 22202

(73) Assignee: NEC CORPORATION

(21) Appl. No.: 09/820,781

(22) Filed: Mar. 30, 2001

(30) Foreign Application Priority Data
Mar. 30, 2000 (JP) 095787/2000

(51) Int. Cl. H01L 27/13; H01L 27/11; H01L 21/20

(52) U.S. Cl. 257/536; 257/66; 257/903; 257/904; 438/382; 438/383

(57) ABSTRACT

A patterned polysilicon film is formed over a silicon substrate with an interlayer insulating film therebetween. Then heavily doped regions as well as a lightly doped region are formed on the polysilicon film. The entire polysilicon film is covered with an SiO₂ film. The polysilicon film is hydrogenated, while an SiNₓ film is formed over the entire SiO₂ film, by LPCVD using a gas comprising nitrogen and hydrogen.

### BACKGROUND OF THE INVENTION

1. Field of the Invention

The present invention relates to a semiconductor device and a manufacturing method therefor. More particularly, the present invention relates to a semiconductor device comprising a resistor and a manufacturing method therefor.

2. Description of the Related Art

In recent years, regarding a semiconductor integrated circuit, there have been cases in which an appropriate impurity is selectively doped into a polysilicon film or an amorphous silicon film so that a part of the polysilicon film or the amorphous silicon film is used as a resistor, and another part or all of the other part is used as wirings or an electrode. In such cases, it is preferable that the part which is used as a resistor has as high a resistance value as possible, while the part which is used as wirings or an electrode has as low a resistance value as possible. In other words, it is preferable that the ratio of the resistance value of the part used as a resistor to the resistance value of the part used as wirings or an electrode be as large as possible.

A high resistance value ratio can be achieved by making the resistance value of the part used as wirings as low as possible, and by making the resistance value of the part used as a resistor, as high as possible. As a simple way to achieve a high resistance value, there is a method in which the amount of an impurity doped into the part used as wirings is increased so as to raise the sheet resistance value of this part. However, when the amount of an impurity doped into the part is increased, the impurity tends to diffuse into other films or layers adjacent to the part. Furthermore, when the doping of an impurity into the part used as wirings is carried out by an ion implantation method, the time required for the ion implantation will be increased as the impurity doping amount is increased. Therefore, there is a limitation in increasing the resistance value ratio by increasing the amount of an impurity to be implanted.

As a method for regulating the resistance value of a polysilicon film or an amorphous silicon film, the following are proposed. For example, according to the method disclosed in Unexamined Japanese Patent Application KOKAI Publication No. H3-160752, a cheraical vapor deposition (CVD) silicon oxide film covering a high-resistant polysilicon resistive layer, and a low-pressure CVD (LPCVD) silicon nitride film covering the CVD silicon oxide film are formed first. The CVD silicon oxide film and the LPCVD silicon nitride film act as interlayer insulating films. Next, a contact hole is formed to pass through the CVD silicon oxide film and the LPCVD silicon nitride film, and then an aluminum film is formed by vapor deposition for use as wirings on the LPCVD silicon nitride film. The aluminum film is connected to the polysilicon layer through the contact hole. After that, the aluminum film is subjected to a patterning treatment to form wirings. Then, a plasma CVD silicon nitride film is formed as a protective film on the thus formed aluminum wirings.

According to the above-described method, the CVD oxide film covers the high-resistant polysilicon resistive layer as an interlayer insulating film, and then the LPCVD silicon nitride film is laminated over the CVD silicon oxide film. By virtue of this, even when the plasma silicon nitride film is formed later as a protective layer, the resistance value of the polysilicon resistive layer is degraded little and the resistance value can be kept constant before and after the formation of the protective film. In other words, a polysilicon resistive layer having a high resistance value is obtained in a stable manner.

Unexamined Japanese Patent Application KOKAI Publication No. S61-161750 discloses a semiconductor device wherein at least one polysilicon resistive region is formed on an oxide film which is formed on the surface of a semiconductor substrate. Furthermore, the semiconductor device has three-layer structure protective films comprising a silicon oxide film, a silicon nitride film formed by CVD at a relatively high temperature, and another silicon nitride film formed by CVD at a relatively high temperature, on a ?art of this at least one polysilicon resistive region. In the above-described configuration, the part of this at least one polysilicon resistive region acts as a high-resistant polysilicon resistor. The semiconductor device also comprises two-layer structure protective films composed of a silicon oxide film and a silicon nitride film formed by plasma CVD at a relatively low temperature on another part of this at least one polysilicon resistive region. Here, the other part of this at least one polysilicon resistive region acts as a low-resistant polysilicon region.

In the semiconductor device disclosed above, the three-layer structure protective films are formed on a part of the polysilicon resistive region, while the two-layer structure protective films are formed on another part of the resistive region. Through this configuration, the two regions having different resistance values from each other are obtained by one step of impurity doping (ion implantation) into the polysilicon resistive region. That is, the impurity doping step for forming a low-resistant region can be omitted.

Furthermore, according to the method disclosed by Unexamined Japanese Patent Application KOKAI Publication No. H4-299566, a CVD silicon oxide film and a CVD silicon nitride film are formed on a semiconductor device having a high-resistant polysilicon region., followed by annealing with an oxygen plasma and a thermal treatment in an nitrogen atmosphere. The CVD silicon oxide film and the CVD silicon nitride film thus formed constitute protective films.

In the method disclosed above, hydrogen or the like which has intruded into the polysilicon crystals in the course of forming the protective films is emitted to peripheral layers such as the CVD silicon oxide film, which are located over and below the polysilicon region. Through this procedure, high-resistant characteristics which the high-resistant polysilicon region inherently possesses can be recovered. The degradation of the transistor properties can also be prevented.

Furthermore, the semiconductor device as disclosed in Unexamined Japenese Patent Application KOKAI Publication No. H6-85175 comprises a metal film over a high-resistant polysilicon region with an insulating film therebetween, and also comprises a plasma CVD nitride film thereon. In this semiconductor device, since the high-resistant polysilicon region is covered with the metal film, a large quantity of hydrogen contained inside and at the interface of the plasma CVD nitride film does not diffuse into the polysilicon region which is located below the metal film. By virtue of this, the fluctuation of the resistance value of the polysilicon region caused by hydrogen can be prevented and a high resistance value is obtained in a stable manner.

However the above-described conventional technologies have the following problems. For example, according to the methods as disclosed in Unexamined Japanese Patent Application KOKAI Publication Nos. S61-161750, H3-160752, or H6-85175, it is not possible to locally change the resistance value of a polysilicon layer, although it is possible to keep high the resistance value of the entire polysilicon layer.

Furthermore, the semiconductor device as disclosed in Unexamined Japanese Patent Application KOKAI Publication No. S61-161750 comprises two regions having different resistance values from each other which are realized by one step of impurity doping (ion implantation) into a polysilicon resistive region. That is, it has a high-resistant region and a low-resistant region. However, the ratio of the resistance value of the low-resistant region to the resistance value of the high-resistant region cannot be increased easily without increasing the impurity doping amount.

### SUMMARY OF THE INVENTION

Accordingly, it is an object of the present invention to provide a semiconductor device comprising a silicon film wherein a heavily doped region, and a lightly doped or non-doped region are formed, and the ratio of the sheet resistance value of the lightly doped or non-doped region to the sheet resistance value of the heavily doped region can be set to a high value, and to provide a manufacturing method therefor.

It is another object of the present invention to provide a semiconductor device wherein the ratio of the OFF resistance value to the ON resistance value of a thin film transistor can be set to a high value, and to provide a manufacturing method therefor.

It is still another object of the present invention to provide a semiconductor device applied to a static random access memory (SRAM) wherein the ratio of the sheet resistance value of the lightly doped or non-doped region for use as a resistor to the sheet resistance value of the heavily doped region for use as wirings can be set to a high value, and to provide a manufacturing method therefor.

To achieve the above-described objects, the invention provides

a semiconductor device comprising:

a silicon film located on an insulating film, the silicon film having a first region doped with an impurity, and a second region adjacent to said first region and doped with an impurity at a concentration lower than that of the first region, or not doped with an impurity;

a silicon oxide film located on said silicon film; and

a silicon nitride film located on said silicon oxide film,

wherein said silicon film comprises hydrogen, in which the hydrogen contents of said first region and second region are different from each other.

### BRIEF DESCRIPTION OF THE DRAWINGS

These objects and other objects and advantages of the present invention will become more apparent upon reading of the following detailed description and the accompanying drawings in which:

FIG. 1 is a plan view showing the configuration of a semiconductor device as described in a first embodiment according to the present invention;

FIG. 2 is a cross-sectional view taken along the A-A′ line of the semiconductor device shown in FIG. 1;

FIG. 3 is a plan view showing the configuration of a semiconductor device as described in a second embodiment according to the present invention;

FIG. 4 is a cross-sectional view taken along the B-B′ line of the semiconductor device shown in FIG. 3;

FIG. 5 is a plan view showing the configuration of a semiconductor device as described in a third embodiment according to the present invention; and

FIG. 6 is a cross-sectional view taken along the C-C′ line of the semiconductor device shown in FIG. 5.

### DESCRIPTION OF THE PREFERRED EMBODIMENTS

In the following descriptions, desirable embodiments according to the present invention will be explained by referring to the drawings.

### First Embodiment

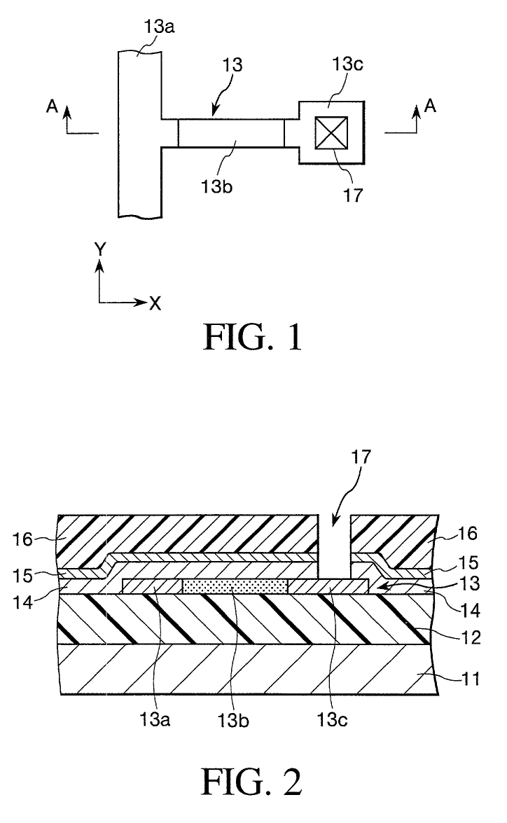

The configuration of the first embodiment according to the present invention is shown in FIGS. 1 and 2. FIG. 1 is a plan view showing the configuration of a semiconductor device as described in the first embodiment, and FIG. 2 is a cross-sectional view taken along the A-A′ line of the semiconductor device shown in FIG. 1.

As is understood from FIGS. 1 and 2, in the semiconductor device of the first embodiment, an interlayer insulating film 12 is formed on the main surface of a single crystal silicon substrate 11 which is equipped with various semiconductor elements (not shown).

On the interlayer insulating film 12, a patterned polysilicon film 13 is formed. The polysilicon film 13 comprises a heavily doped region 13a, a lightly doped region 13b, and a heavily doped region 13c. The lightly doped region 13b has a relatively high sheet resistance value, and acts as a resistor. The two heavily doped regions 13a and 13c have relatively low sheet resistance values and act as wirings. The impurity concentrations of the heavily doped regions 13a and 13c are substantially the same.

On the interlayer insulating film 12 and on the polysilicon film 13, a silicon dioxide (SiO₂) film is formed. A silicon nitride (SiNₓ: x is a positive real number) film 15 is formed on the SiO₂ film 14. The SiO₂ film 14 and the SiNₓ film 15 constitute protective films for the polysilicon film 13 (that is, the resistor and the wirings) located below them. The SiO₂ film 14 and the SiNₓ film 15 are formed over the entire main surface of the substrate 11.

On the SiNₓ film 15, an interlayer insulating film 16 is formed in such a way that it covers the entire surface of the substrate 11. A contact hole 17 is formed, passing through the interlayer insulating film 16, the SiO₂ film 14, and the SiNₓ film 15. The bottom end of the contact hole 17 reaches the heavily doped region 13c of the polysilicon film 13. On the interlayer insulating film 16, there is formed an electroconductive film (not shown) for use as wirings. The electroconductive film is connected to the heavily doped region 13c via the contact hole 17.

As is understood from FIG. 1, the heavily doped region 13a is in the shape of a rectangular strip extending along the Y-direction in FIG. 1. The lightly doped region 13b is also in the shape of a rectangular strip, extending along the X-direction in FIG. 1. One end of the lightly doped region 13b is connected to the heavily doped region 13a. The heavily doped region 13c is of a rectangular shape and is connected to the other end of the lightly doped region 13b. The contact hole 17 is located in such a way that it is shown as overlapped with the heavily doped region 13c in FIG. 1.

The heavily doped region 13a is connected to the semiconductor elements or other wirings (both not shown) formed on the substrate 11. The heavily doped region 13c is connected to the electroconductive film (not shown) for use as wirings formed on the interlayer insulating film 16 via the contact hole 17. Through these connections, the resistor constituted by the lightly doped region 13b is connected to the semiconductor elements or other wirings formed below the interlayer insulating film 12, via the heavily doped region 13a, and is connected to the wirings formed over the interlayer insulating film, via the heavily doped region 13c.

Next, the manufacturing method for a semiconductor device as described in the first embodiment having the above-described configuration, will be explained. To begin with, the interlayer insulating film 12 is formed on the main surface of the single crystal silicon substrate 11 so that the film covers the entire main surface. There is no specific limitation to the material and the thickness of the interlayer insulating film 12.

Next, the polysilicon film 13 is formed on the interlayer insulating film 12 by low-pressure CVD (LPCVD). The thicknesses of the polysilicon film 13 is set to a suitable value, for example, in the range of from 30 nm to 100 nm. Then, the polysilicon film 13 is subjected to photolithography and etching to provide a pattern as shown in FIG. 1. The polysilicon film may comprise oxygen to raise the sheet resistance value. Furthermore, the polysilicon film 13 may be subjected to a surface oxidation treatment, as necessary, to stabilize the film quality.

Subsequently, the patterned polysilicon film 13 is subjected to selective doping with an impurity by ion implantation to form the heavily doped region 13a, the lightly doped region 13b, and the heavily doped region 13c. The amounts of the impurity doped into the heavily doped regions 13a and 13c are each set so that the ion implantation dosages are in the range of from 5×10¹⁴ atoms/cm² to 2×10¹⁶ atoms/cm². The amount of the impurity doped into the lightly doped region 13b is set so that the ion implantation dosage is not more than 3×10¹⁴ atoms/cm².

There is no specific limitation to the type of impurity for use in the impurity implantation, and any impurity can be used. As an n-type impurity, phosphorus (P), arsenic (As) or the like can be used, for example. As a p-type impurity, boron (B) or the like can be used, for example.

Each of the heavily doped region 13a, the lightly doped region 13b, and the heavily doped region 13c in the polysilicon film 13 is formed by depositing an n-type or p-type polysilicon film 13 doped with an impurity at a specific concentration through LPCVD, and then by selectively doping the n-type or p-type polysilicon film 13 with an n-type or p-type impurity. Or, it may be possible to form a polysilicon film 13 by LPCVD without doping with an impurity, followed by selectively doping parts of the polysilicon film 13 with an n-type or p-type impurity at a high concentration. In other words, any method is acceptable as long as the heavily doped region 13a, the lightly doped region 13b, and the heavily doped region 13c can be selectively formed.

Next, the SiO₂ film 14 is formed on the interlayer insulating film 12 in such a way that it covers the entire surface of the substrate 11, by ambient-pressure CVD, LPCVD or the like. The entire patterned polysilicon film 13 is covered with the SiO₂ film 14. The thickness of the SiO₂ film 14 is set in the range of from 50 nm to 200 nm, for example.

Next, the SiNₓ film 15 is formed on the SiO₂ film 14 by LPCVD using a raw material gas comprising nitrogen and hydrogen so that it covers the entire surface of the substrate 11. The entire SiO₂ film 14 is covered with the SiNₓ film 15. The thickness of the SiNₓ film 15 is set in the range of from 10 nm to 50 nm, for example. As the raw material gas comprising nitrogen and hydrogen, a gas mixture of silane dichloride (SiH₂Cl₂) and ammonia (NH₃) can be used, for example, at a mixing ratio on the level of SiH₂Cl₂:NH₃=1:10. A typical chamber temperature is in the range of from 700° C. to 800° C., and a typical chamber pressure is in the range of from 39.9966 Pa to 53.3288 Pa (from 0.3 Torr to 0.4 Torr).

Through LPCVD using the raw material gas comprising nitrogen and hydrogen, the polysilicon film 13 located below the SiNx film 15 is hydrogenated, while the SiNx film 15 is formed. The rate of hydrogenation of the polysilicon film 13 varies as the impurity concentration, and therefore, the hydrogen contents of the heavily doped regions 13a and 13c are different from that of the lightly doped region 13b in the polysilicon film 13 after the deposition of the SiNₓ film 15. Therefore, the degrees of changes of the sheet resistance values of the heavily doped regions 13a and 13c are different from that of the lightly doped region 13b after the deposition of the SiNₓfilm 15.

Since the SiNₓ film 15 is formed for the purpose of protection and modification (hydrogenation) of the polysilicon film 13 which is located below the film, almost any film thickness can be chosen. The lower limit is about 10 nm. It is because the thickness on the level of about 10 nm is sufficient to effectively modify the polysilicon film 13 by hydrogenation. There is no special upper limit. However, it is not preferable to have a too thick film so as to easily form the contact hole 17 with a good profile by plasma etching. Considering these, it is preferable to set the thickness of the SiNₓ film 15 in the range of from 10 nm to 50 nm.

Subsequently, the interlayer insulating film 16 is formed on the SiNₓ film 15 so as to cover the entire surface of the substrate 11 by CVD or the like. There is no specific limitation to the thickness of the interlayer insulating film 16.

After that, the contact hole 17 is formed by photolithography and etching so that it passes through the interlayer insulating film 16, the SiO₂ film 14, and the SiNₓ film 15 to reach the heavily doped region 13c in the polysilicon film 13.

Lastly, the electroconductive film (not shown) is formed on the interlayer insulating film 16 for forming wirings. The electroconductive film is connected to the heavily doped region 13c via the contact hole 17. Accordingly, the semiconductor device is formed as shown in FIGS. 1 and 2.

As explained above, in the semiconductor device as described in the first embodiment, the polysilicon film 13 is covered with the SiO₂ film 14, and with the SiNₓ film 15 formed by LPCVD using a raw material gas comprising nitrogen and hydrogen. Due to this, hydrogen contained in the raw material gas for use in forming the SiNₓ film 15 passes through the SiO₂ film 14 to reach the polysilicon film 13, with the result that the polysilicon film 13 is hydrogenated.

Here, the hydrogen contents of the heavily doped regions 13a and 13c are different from that of the lightly doped region 13b after the deposition of the SiNₓ film 15, depending on the difference of the impurity concentrations. The resistance value of the polysilicon film changes by hydrogenation, and therefore, the degrees of changes of the sheet resistance values of the heavily doped regions 13a and 13c are different from that of the lightly doped region 13b, depending on the difference of the hydrogen contents.

Accordingly, the ratio of the sheet resistance value of the heavily doped regions 13a and 13c which act as wirings to the sheet resistance value of the lightly doped region 13b which acts as a resistor, can be raised without increasing the amount of the doped impurity.

Based on the experiments according to the present invention, the following results of from (a) to (d) were obtained.

(a) The SiNₓ film 15 was formed over the polysilicon film 13 with the SiO₂ film 14 therebetween by setting the thickness of the polysilicon film 13 in the range of from 30 nm to 100 nm, and by setting the impurity amount in the lightly doped region 13b to a value not more than 3×10¹⁴ atoms/cm². Hereupon, the SiNₓ film 15 formation was carried out by LPCVD using a gas comprising nitrogen and hydrogen. At the stage, the sheet resistance value of the lightly doped region 13b increased about 10 times in comparison with the case in which only the SiO₂ film 14 was formed on the polysilicon film 13. It was found through this experiment that the sheet resistance value of the lightly doped region 13b was increased by hydrogenation.

(b) Hydrogenation of the polysilicon film 13 was made possible by performing a high-temperature treatment in a gas mixture of hydrogen and nitrogen. However, the degree of the increase of the sheet resistance value of the lightly doped region 13b was far larger in the above-described first embodiment.

(c) When the SiNₓ film 15 was formed directly on the polysilicon film 13, the state of the interface of the films became unstable, with the result that the resistance characteristics of the polysilicon film 13 became unstable. Owing to this, it was necessary to form the SiNₓ film 15 over the polysilicon film 13 with the SiO₂ film therebetween.

(d) It was found that when the thickness of the SiNₓ film 15 was not less than 10 nm, modification of the polysilicon film 13 by hydrogenation was sufficiently attained. Furthermore, it was found that it was preferable to set the thickness of the SiNₓ film 15 in the range of from 10 nm to 50 nm, considering the etching profile or the like of the contact hole 17.

It is noted that an amorphous silicon film may be used instead of the polysilicon film 13, in a semiconductor device as described in the first embodiment.

### Second Embodiment

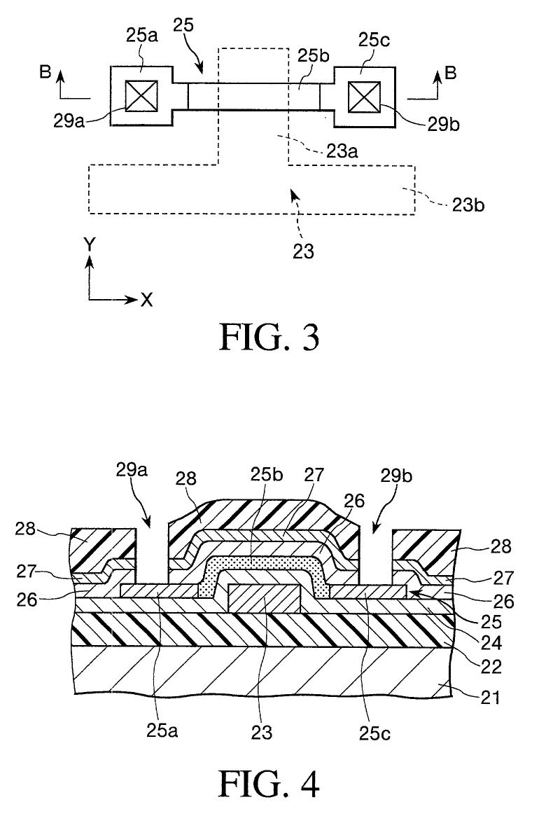

FIGS. 3 and 4 show the configuration of a semiconductor device as described in the second embodiment according to the present invention. FIG. 3 is a plan view showing the configuration of a semiconductor device as described in the second embodiment, and FIG. 4 is a cross-sectional view taken along the B-B′ line of the semiconductor device shown in FIG. 3. The semiconductor device corresponds to the case in which the present invention is applied to a thin film transistor (TFT).

As is understood from FIGS. 3 and 4, in the semiconductor device as described in the second embodiment, an interlayer insulating film 22 is formed on the main surface of a single crystal silicon substrate 21. A gate electrode 23 is formed on the interlayer insulating film 22. And a gate insulating film 24 is formed on the interlayer insulating film 22 in such a way that it covers the gate electrode 23.

A patterned polysilicon film 25 is formed on the gate insulating film 24 in such a way that it overlays the gate electrode 23. The polysilicon film 25 comprises a heavily doped region 25a, a lightly doped region 25b, and a heavily doped region 25c. The lightly doped region 25b has a relatively high sheet resistance value and acts as a channel region of the TFT. The two heavily doped regions 25a and 25c have relatively low sheet resistance values and act as a source region or a drain region of the TFT, respectively. It can be arbitrarily chosen which of the two heavily doped regions 25a and 25c is used as the source region or the drain region of the TFT. It is noted that the impurity concentrations of the heavily doped regions 25a and 25c are substantially the same.

An SiO₂ film 26 is formed on the gate insulation film 24 and on the polysilicon film 25. An SiNₓ film 27 is formed on the SiO₂ film 26. The SiO₂ film 26 and the SiNₓ film 27 are constituted to form protective films for the polysilicon film 25 which is located below. The SiO₂ film and the SiNₓ film cover the entire surface of the substrate 21.

An interlayer insulating film 28 is formed on the SiNₓ film 27 so as to cover the entire surface of the substrate 21. Contact holes 29a and 29b are formed, passing through the interlayer insulating film 28, the SiO₂ film 26, and the SiNₓ film 27. The contact holes 29a and 29b reach the two heavily doped regions 25a and 25c in the polysilicon film 25, respectively. On the interlayer insulating film 28, an electroconductive film (not shown) for use as wirings is formed to connect to the heavily doped regions 25a and 25c respectively via the contact holes 29a and 29b.

As shown in FIG. 3, the lightly doped region 25b is in the shape of a rectangular strip, extending along the X-direction in FIG. 3. The two heavily doped regions 25a and 25c acting as a source region or a drain region respectively are both of a rectangular shape, connecting to either end of the lightly doped region 25b, respectively. A part 23a of the gate electrode 23 is in the shape of a rectangular strip, extending along the Y-direction in FIG. 3.

Next, the manufacturing method for a semiconductor device having the above-described configuration as described in the second embodiment, will be explained. To begin with, the interlayer insulating film 22 is formed on the main surface of the single crystal silicon substrate 21 in such a way that it covers the entire main surface. There is no specific limitation to the material and the thickness of the interlayer insulating film 22. Subsequently, the gate electrode 23 is formed on the interlayer insulating film 22, and the gate insulating film 24 is formed to cover the gate electrode 23, according to a known method.

Next, the polysilicon film 25 is formed on the gate insulating film 24 by LPCVD. The thickness of the polysilicon film 25 is set to an appropriate value, for example, in the range of from 30 nm to 100 nm. Then, the polysilicon film 25 is subjected to photolithography and etching to form a pattern having the shape shown in FIG. 3. The polysilicon film 25 may comprise oxygen to raise the sheet resistance value. The polysilicon film 25 may also be subjected to a surface treatment, as necessary, to stabilize the film quality.

Next, the patterned polysilicon film 25 is subjected to selective doping with an impurity by ion implantation to form the heavily doped region 25a, the lightly doped region 25b, and the heavily doped region 25c. The amounts of the impurity doped into the heavily doped regions 25a and 25c are set so that the ion implantation dosages are in the range of from 5×10¹⁴ atoms/cm² to 2×10¹⁶ atoms/cm². The amount of the impurity doped into the lightly doped region 25b is set so that the ion implantation dosage is not more than 3×10¹⁴ atoms/cm².

There is no specific limitation to the type of impurity for use in the impurity implantation, and any impurity can be used. As an n-type impurity, phosphorus (P), arsenic (As) or the like can be used, for example. As a p-type impurity, boron (B) or the like can be used, for example.

Each of the heavily doped region 25a, the lightly doped region 25b, and the heavily doped region 25c in the polysilicon film 25 can be formed by depositing an n-type or p-type polysilicon film 25 doped with an impurity at a specific concentration through LPCVD, and then by selectively doping the n-type or p-type polysilicon film 25 with an n-type or p-type impurity. Or, it may be possible to form the polysilicon film 25 by LPCVD without doping with an impurity, followed by selectively doping parts of the polysilicon film 25 with an n-type or p-type impurity at a high concentration. In other words, any method is acceptable as long as the heavily doped region 25a, the lightly doped region 25b, and the heavily doped region 25c can be selectively formed.

Next, the SiO₂ film 26 is formed on the gate insulating film 24 in such a way that it covers the entire surface of the substrate 21, by ambient-pressure CVD, LPCVD or the like. The thickness of the SiO₂ film 26 is set in the range of from 50 nm to 2,000 nm, for example.

Next, the SiNx film 27 is formed on the SiO₂ film 26 by CVD using a raw material gas comprising nitrogen and hydrogen so that it covers the entire surface of the substrate 21. The entire SiO₂ film 26 is covered with the SiNₓ film 27. The thickness of the SiNₓ film 27 is set in the range of from 10 nm to 50 nm, for example. As the raw material gas comprising nitrogen and hydrogen, for example, a gas mixture of silane dichloride (SiH₂Cl₂) and ammonia (NH₃) can be used at a mixing ratio, for example, on the level of SiH₂Cl₂:NH₃=1:10. A typical chamber temperature is in the range of from 700° C. to 800° C., and a typical chamber pressure is in the range of from 39.9966 Pa to 53.3288 Pa (from 0.3 Torr to 0.4 Torr).

Through LPCVD using the raw material gas comprising nitrogen and hydrogen, the polysilicon film 25 located below the SiNₓ film 27 is hydrogenated, while the SiNₓ film 27 is formed. The rate of hydrogenation of the polysilicon film 25 varies as the impurity concentration, and therefore, the hydrogen contents of the heavily doped regions 25a and 25c are different from that of the lightly doped region 25b, in the polysilicon film 25 after the deposition of the SiNₓ film 27. Therefore, the degrees of changes of the sheet resistance values of the heavily doped regions 25a and 25c are different from that of the lightly doped region 25b.

The SiNₓ film 27 is formed for the purpose of protection and modification (hydrogenation) of the polysilicon film 25. It is preferable to set the thickness of the SiNₓ film 27 in the range of from 10 nm to 50 nm so as to easily form the contact holes 29a and 29b with a good profile by plasma etching.

Subsequently, the interlayer insulating film 28 is formed on the SiNₓ film 27 so as to cover the entire surface of the substrate 21 by CVD or the like. Then, the contact holes 29a and 29b are formed by a known method to reach the heavily doped regions 25a and 25c of the polysilicon film 25, respectively, through the interlayer insulating film 28, the SiO₂ film 26, and the SiNₓ film 27. Lastly, the electroconductive film (not shown) for use as wirings is formed on the interlayer insulating film 28. Through these procedures, the semiconductor device as shown in FIGS. 3 and 4 is obtained.

As explained above, in the semiconductor device as described in the second embodiment, the polysilicon film 25 is covered with the SiO₂ film 26, and with the SiNₓ film 27 formed by LPCVD using the raw material gas comprising hydrogen. Owing to this, the hydrogen contained in the raw material gas used for forming the SiNₓ film 27 reaches the polysilicon film 25 through the SiO₂ film 26 to hydrogenate the polysilicon film 25.

Here, after the formation of the SiNₓ film 27, the hydrogen contents of the heavily doped regions 25a and 25c are different from that of the lightly doped region 25b, depending on the difference of the impurity concentrations. The resistance value of the polysilicon film changes by hydrogenation, and the degrees of changes of the sheet resistance values of the heavily doped regions 25a and 25c are different from that of the lightly doped region 25b, depending on the difference of the hydrogen contents.

Accordingly, the ratio of the sheet resistance values of the heavily doped regions 25a and 25c to the sheet resistance value of the lightly doped region 25b, can be raised without increasing the impurity doping amount.

Hereupon, the heavily doped regions 25a and 25c act as a source region or a drain region of a TFT, and the lightly doped region 25b acts as the channel region, respectively. Thus, it is possible to raise the OFF resistance value without changing the ON resistance value of a TFT. In other words, the ratio of the OFF resistance value to the ON resistance value of a TFT can be raised without increasing the impurity concentration.

It is noted that an amorphous silicon film may be used instead of the polysilicon film 25 for the semiconductor device as described in the second embodiment.

### Third Embodiment

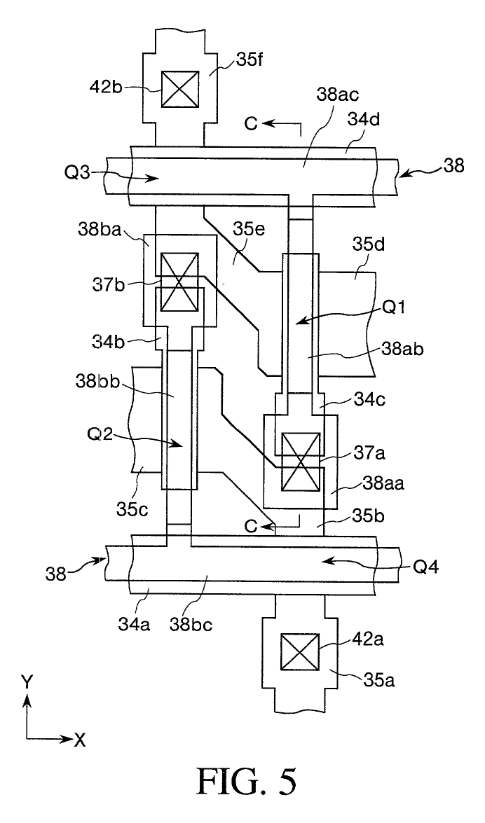

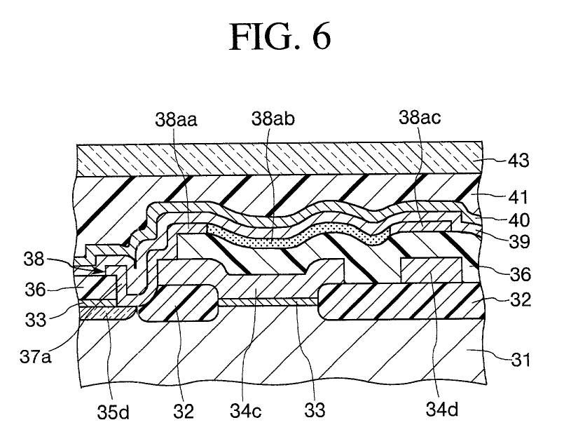

FIGS. 5 and 6 show the configuration of a semiconductor device as described in the third embodiment of the present invention. FIG. 5 is a plan view, and FIG. 6 is a cross-sectional view taken along the C-C′ line of the semiconductor device shown in FIG. 5. In this embodiment, the semiconductor device is used for a static random access memory (SRAM). To simplify the explanation, only one memory cell is shown here, which comprises memory transistors Q1 and Q2, transmission transistors Q3 and Q4, and a loading resistor.

As is understood from FIGS. 5 and 6, an element isolation insulating film 32 is formed selectively on the main surface of a single crystal silicon substrate 31 in the semiconductor device as described in the third embodiment. Impurity diffusion regions 35a, 35b, 35c, 35d,, 35e, and 35f are formed on the active regions defined by the element isolation insulating, film 32, respectively.

The impurity diffusion regions 35a and 35b act as a source region or a drain region of the transmission transistor Q4, respectively. The impurity diffusion regions 35c and 35b act as a source region or a drain region of the memory transistor Q2, respectively. The impurity diffusion regions 35d and 35e act as a source region or a drain region of the memory transistor Q2, respectively. The impurity diffusion regions 35e and 35f act as a source region or a drain region of the transmission transistor Q3, respectively. It is noted that either one of the two impurity diffusion regions constituting a transistor can be used arbitrarily as a source region or a drain region in the above-described transistors from Q1 to Q4.

On the surface of the substrate 31, gate insulating films 33 are formed between the impurity diffusion regions 35a and 35b, between the impurity diffusion regions 35b and 35c, between the impurity diffusion regions 35d and 35e, and between the impurity diffusion regions 35e and 35f, respectively. Gate electrodes 34a, 34b, 34c, and 34d are formed on the gate insulating films 33, respectively.

On the surface of the substrate 31, an interlayer insulating film 36 is formed so as to cover the element isolation insulating film 32, and the gate electrodes 34a, 34b, 34c, and 34d. Contact holes 37a and 37b are formed in the interlayer insulating film 36. The contact holes 37a and 37b reach the impurity diffusion regions 35b and 35c, respectively, passing through the interlayer insulating film 36 and the gate insulating films 33 thereunder. Both impurity diffusion regions 35b and 35c act as memory nodes.

A patterned polysilicon film 38 is formed on the interlayer insulating film 36. The polysilicon film 38 comprises a heavily doped region 38aa, a lightly doped region 38ab, and a heavily doped region 38ac. The lightly doped region 38ab has a relatively high sheet resistance value, and acts as a loading resistor for the memory transistor Q1. The two heavily doped regions 38aa and 38ac have relatively low sheet resistance values, and act as wirings, respectively. The impurity concentrations of the heavily doped regions 38aa and 38ac are substantially the same. The heavily doped region 38aa is connected to the impurity diffusion region 35b via the corresponding contact hole 37a.

The polysilicon film 38 also comprises a heavily doped region 38ba, a lightly doped region 38bb, and a heavily doped region 38bc. The lightly doped region 38bb has a relatively high sheet resistance value, and acts as a loading resistor for the memory transistor Q2. The two heavily doped regions 38ba and 38bc have relatively low sheet resistance values, and act as wirings, respectively. The impurity concentrations of the heavily doped regions 38ba and 38bc are substantially the same. The heavily doped region 38ba is connected to the impurity diffusion region 35c via the corresponding contact hole 37b.

An SiO₂ film 39 is formed on the interlayer insulating film 36 and the polysilicon film 38. An SiNₓ film 40 is formed on the SiO₂ film 39. The SiO₂ film 39 and the SiNₓ film 40 act as protective films for the polysilicon film 38 therebelow. The SiO₂ film 39 and the SiNₓ film 40 cover the entire surface of the substrate 31.

On the SiNₓ film 40, an interlayer insulating film 41 is formed so as to cover the entire surface of the substrate 31. Contact holes 42a and 42b are formed, passing through the interlayer insulating film 41, the SiO₂ film 39, and the SiNₓ film 40. The contact holes 42a and 42b reach the impurity diffusion regions 35a and 35f, respectively. A metal film 43 which constitutes bit lines (not shown), is formed on the interlayer insulating film 41.

As shown in FIG. 5, the two lightly doped regions 38ab and 38bb are both in the shape of a rectangular strip, extending along the Y-direction in FIG. 5. The two heavily doped regions 38aa and 38ba acting as wirings, are both roughly of a rectangular shape and are connected to either end of each of the lightly doped regions 38ab and 38bb, respectively. The other two heavily doped regions 38ac and 38bc acting as wirings, are both roughly in the shape of a strip, and are connected to the other end of each of the lightly doped regions 38ab and 38bb, respectively.

The gate electrodes 34a and 34d are both roughly in the shape of a strip, extending along the X-direction in FIG. 5. The gate electrodes 34b and 34c are also both in the shape of a strip, extending along the Y-direction in FIG. 5.

Here, it is noted that an amorphous silicon film may be used instead of the polysilicon film 38. A polysilicon film or an amorphous silicon film having a sheet resistance value raised by the addition of oxygen, can also be used.

Next, a manufacturing method for the semiconductor device which has the above-described configuration as described in the third embodiment, will be explained. To begin with, the element isolation insulating film 32 is selectively formed on the main surface of the single crystal silicon substrate 31 according to a known method. Then, the gate insulating films 33 are formed by thermal oxidation between the impurity diffusion regions 35a and 35b, between the impurity diffusion regions 35b and 35c, between the impurity diffusion regions 35d and 35e, and between the impurity diffusion regions 35e and 35f, respectively. Furthermore, the gate electrodes 34a, 34b, 34c, and 34d are formed, respectively, on the gate insulating films 33 according to a known method.

Next, an impurity is selectively introduced into each active region defined by the element isolation insulating film 32, according to ion implantation so as to form the impurity diffusion regions 35a, 35b, 35c, 35d, 35e, and 35f. The impurity diffusion regions 35a, 35b, 35c, 35d, 35e, and 35f are formed in a self-aligned way to the corresponding gate electrodes 34a, 34b, 34c, and 34d, respectively.

Next, the interlayer insulating film 36 is formed on the main surface of the substrate 31 so as to cover the element isolation insulating film 32, and the gate electrodes 34a, 34b, 34c, and 34d. There is no specific limitation to the material or the thickness of the interlayer insulating film 36. Subsequently, the contact holes 37a and 37b are formed through the interlayer insulating film 36 and the gate insulating films 33 so as to reach the impurity diffusion regions 35b and 35c, respectively.

Next, the polysilicon film 38 is formed on the interlayer insulating film 36 by LPCVD. Then, patterning is carried out as shown in FIG. 5. The thickness of the polysilicon film 38 is set to an appropriate value, for example, in the range of from 30 nm to 100 nm. The polysilicon film 38 comprises the heavily doped region 38aa, the lightly doped region 38ab, the heavily doped region 38ac, the heavily doped region 38ba, the lightly doped region 38bb, and the heavily doped region 38bc. The two heavily doped regions 38aa and 38ba are connected to the impurity diffusion region 35b and 35c (or memory nodes) via the corresponding contact holes 37a and 37b, respectively.

The polysilicon film 38 may comprise oxygen so as to raise the sheet resistance value. The polysilicon film 38 may also be subjected to a surface oxidation treatment to stabilize the film quality, as necessary.

Next, the patterned polysilicon film 38 is subjected to selective doping with an impurity by ion implantation to form the heavily doped regions 38aa and 38ba, the lightly doped regions 38ab and 38bb, and the heavily doped regions 38ac and 38bc. The amounts of the impurity doped into the heavily doped regions 38aa, 38ba, 38ac, and 38bc are set so that the ion implantation dosages are in the range of from 5×10¹⁴ atoms/cm² to 2×10¹⁶ atoms/cm². The amounts of the impurity doped into the lightly doped regions 38ab and 38bb are set so that the ion implantation dosages are not more than 3×10¹⁴ atoms/cm².

Next, the SiO₂ film 39 is formed by ambient-pressure CVD, LPCVD or the like on the interlayer insulating film 36 so as to cover the entire surface of the substrate 31. The SiO₂ film 39 covers the entire patterned polysilicon film 38. The thickness of the SiO₂ film 39 is set, for example, in the range of from 50 nm to 200 nm.

Next, the SiNₓ film 40 is formed on the SiO₂ film 39 by LPCVD using a raw material gas comprising hydrogen so as to cover the entire surface of the substrate 31. The SiNₓ film 40 covers the entire SiO₂ film 39. The thickness of the SiNₓ film 40 is set, for example, in the range of from 10 nm to 50 nm. As the raw material gas comprising hydrogen, for example, a gas mixture of silane dichloride (SiH₂Cl₂) and ammonia (NH₃) can be used at a mixing ratio, for example, on the level of SiH₂Cl₂:NH₃=1:10. A typical chamber temperature is from 700° C. to 800° C., and a typical chamber pressure is from 39.9966 Pa to 53.3288 Pa (from 0.3 Torr to 0.4 Torr).

By LPCVD using the raw material gas comprising nitrogen and hydrogen, the polysilicon film 38 located below the SiNₓ film 40 is hydrogenated, while the SiNₓ film 40 is formed. The hydrogenation rate of the polysilicon film 38 varies depending on the impurity concentrations. Therefore, the hydrogen contents of the heavily doped regions 38aa, 38ba, 38ac, and 38bc are different from those of the lightly doped regions 38ab and 38bb, in the polysilicon film 38 after the deposition of the SiNₓ film 40. The sheet resistance value of the polysilicon film 38 changes by hydrogenation, and therefore, the degrees of changes of the sheet resistance values of the heavily doped regions 38aa, 38ba, 38ac, and 38bc are different from those of the lightly doped regions 38ab and 38bb.

The SiNₓ film 40 is formed for the purpose of protection and modification (hydrogenation) of the polysilicon film 38. It is preferable to set the thickness of the SiNₓ film 40 in the range of from 10 nm to 50 nm so as to easily form the contact holes 42a and 42b with a good profile by plasma etching.

Subsequently, the interlayer insulating film 41 is formed by CVD or the like on the SiNₓ film 40 so as to cover the entire surface of the substrate 31. Then, the contact holes 42a and 42b are formed by a known method to reach the impurity diffusion regions 35a and 35f, respectively, through the interlayer insulating film 41, the SiO₂ film 39, and the SiNₓ film 40. Lastly, the metal film 43 for use as wirings, which constitutes bit lines (not shown), is formed on the interlayer insulating film 41. Through these procedures, the semiconductor device as shown in FIGS. 5 and 6 is obtained.

As explained above, in the semiconductor device as described in the third embodiment, the polysilicon film 38 is covered with the SiO₂ film 39, and with the SiNₓ film 40 formed by LPCVD using a raw material gas comprising hydrogen. Owing to this, the hydrogen contained in the raw material gas used for forming the SiNₓ film 40 reaches the polysilicon film 38 through the SiO₂ film 39 to hydrogenate the polysilicon film 38.

Here, after the formation of the SiNₓ film 40, the hydrogen contents of the heavily doped regions 38aa, 38ba, 38ac, and 38bc are different from those of the lightly doped regions 38ab and 38bb, depending on the impurity concentrations. The resistance value of the polysilicon film changes by hydrogenation, and therefore, the degrees of changes of the sheet resistance values of the heavily doped regions 38aa, 38ba, 38ac, and 38bc are different from those of the lightly doped regions 38ab and 38bb, respectively, depending on the difference of the hydrogen contents.

Accordingly, the ratio of the sheet resistance values of the heavily doped regions 38aa, 38ba, 38ac, and 38bc acting as wirings, to the sheet resistance values of the lightly doped regions 38ab and 38bb acting as loading resistors, can be raised without increasing the impurity concentrations.

Furthermore, in the contact hole 37a, the gate electrode 34c and the impurity diffusion region 35b are well connected to each other with a low parasite resistance value via the heavily doped region 38aa. In the contact hole 37b, too, the gate electrode 34b and the impurity diffusion region 35e are well connected to each other with a low parasite resistance value via the heavily doped region 38ba.

Furthermore, the semiconductor device, in which the polysilicon film 38 is used as a loading resistor and wirings as described in the third embodiment above, contributes to a higher integration of an SRAM.

The present invention is not limited to the first to third embodiments described above. For example, in the first to third embodiments, it was described that a polysilicon film or an amorphous silicon film comprises a “heavily doped region(s)” and a “lightly doped region(s)”. However, a “non-doped region(s)” may be used instead of the “lightly doped region(s)”. hi other words, the polysilicon film or the amorphous silicon film may contain the “heavily doped region(s)” and the “non-doped region(s)”.

Furthermore, while the explanations are made for the second and third embodiments as described above, in which the present invention is applied to a TFT and an SRAM, the present invention may be applied to any type of semiconductor device other than these, as long as it is a semiconductor device having a silicon film comprising a “heavily doped region(s)”, and a “lightly doped region(s)”, or a “non-doped region(s)”.

Furthermore, in the first to third embodiments as described above, the silicon nitride film is formed using a gas mixture of silane dichloride and ammonia. Here, the mixing ratio of the above-described gas mixture is not limited to those described in the above-described embodiments. Also, any gas may be used as the gas for deposition as long as it contains nitrogen and hydrogen, and a mixture of a gas comprising hydrogen such as a different type of silane gas and a gas comprising nitrogen such as nitrogen gas may be used. Also, the reaction conditions such as the temperature and the pressure at the time of silicon nitride film deposition are not limited to those described above.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiment (embodiments). Various modifications made within the meaning of an equivalent of the claims of the invention and within the claims are to be regarded to be in the scope of the present invention.

This application is based on Japanese Patent Application No. 2000-095787 filed on Mar. 30, 2000 and including specification, claims, drawings and summary. The disclosure of the above Japanese Patent Application is incorporated herein by reference in its entirety.

What is claimed is:

1. A semiconductor device comprising:
a silicon film Located on an insulating film, the silicon film having a first region doped with an impurity, and a second region adjacent to said first region and doped with an impurity at a concentration lower than that of the first region, or not doped with an impurity;
a silicon oxide film located on said silicon film; and
a silicon nitride film located on said silicon oxide film,
wherein said silicon film comprises hydrogen, in which the hydrogen contents of said first and second regions are different from each other.

2. A semiconductor device according to claim 1, wherein said first and second regions have the same type of electroconductivity.

3. A semiconductor device according to claim 1, wherein said silicon film is a polysilicon film.

4. A semiconductor device according to claim 1, wherein said silicon nitride film has a thickness in the range of from 10 nm to 50 nm.

5. A semiconductor device according to claim 1, wherein said first region has an impurity doped at a concentration in the range of from 5×10¹⁴ atoms/cm² to 2×10¹⁶ atoms/cm².

6. A semiconductor device according to claim 1, wherein said second region has an impurity doped at a concentration not more than 3×10¹⁴ atoms/cm².

7. A semiconductor device according to claim 1, wherein said silicon film has a thickness in the region of from 30 nm to 100 nm.

8. A semiconductor device comprising:
a silicon film located on an insulating film, the silicon film having two first regions doped with an impurity, and having a second region sandwiched by said first regions and doped with an impurity at a concentration lower than those of the first regions, or not doped with an impurity;
a silicon oxide film located on said silicon film; and
a silicon nitride film located on said silicon oxide film,
wherein
said silicon film comprises hydrogen, in which the hydrogen contents of said first and second regions are different from each other; and
said two first regions constitute a source region or a drain region, respectively, and said second region constitutes a channel region, in a thin film transistor (TFT).

9. A semiconductor device comprising:
a silicon film located on an insulating film, the silicon film having two first regions doped with an impurity, and having a second region sandwiched by said first regions and doped with an impurity at a concentration lower than those of the first regions, or not doped with an impurity;
a silicon oxide film located on said silicon film; and
a silicon nitride film located on said silicon oxide film,
wherein
said silicon film comprises hydrogen, in which the hydrogen contents of said first and second regions are different from each other; and
said first regions constitute wiring of a memory cell for a static random access memory (SRAM), and said second region constitutes a loading resistor of the memory cell for the SRAM.

10. A method for manufacturing a semiconductor device comprising the steps of:
forming a silicon film on an insulating film;
selectively doping said silicon film with an impurity to form a first doped region and a second region adjacent to said first region and doped with an impurity at a concentration lower than that of The first region, or not doped with an impurity;
forming a silicon oxide film on said silicon film; and
forming a silicon nitride film on said silicon oxide film and hydrogenating said silicon film at the same time, by low-pressure chemical vapor deposition (LPCVD) using a gas comprising nitrogen and hydrogen.

11. A method for manufacturing a semiconductor device according to claim 10, wherein a gas mixture of silane dichloride and ammonia is used as said gas comprising nitrogen and hydrogen.

12. A method for manufacturing a semiconductor device according to claim 11, wherein the mixing ratio of the silane dichloride to the ammonia is;
(the silane dichloride):(the ammonia)=1:10.

13. A method for manufacturing a semiconductor device according to claim 10, wherein said silicon nitride film is formed with a thickness in the range of from 10 nm to 50 nm.

14. A method for manufacturing a semiconductor device according to claim 10, wherein said first region is doped with an impurity at a concentration in the range of from 5×10¹⁴ atoms/cm² to 2×10¹⁶ atoms/cm².

15. A method for manufacturing a semiconductor device according to claim 10, wherein said second region is doped with an impurity at a concentration not more than 3×10¹⁴ atoms/cm.

16. A method for manufacturing a semiconductor device according to claim 10, wherein said silicon film is formed with a thickness in the range of from 30 nm to 100 nm.
